(19) United States
(12) Patent Application Publication
(10) Pub. No.: US 2025/0199053 A1
(43) Pub. Date: Jun. 19, 2025

(54) SYSTEM AND METHOD FOR DETERMINING ELECTRONIC DEVICE THERMAL RESISTANCE CHARACTERISTICS

(71) Applicant: NXP USA, Inc., Austin, TX (US)

(72) Inventors: Michael Eugene MAJERUS, Chandler, AZ (US); Jamison Michael MCCARVILLE, Tempe, AZ (US)

(21) Appl. No.: 18/545,600

(22) Filed: Dec. 19, 2023

(51) Int. Cl. G01R 31/26

(52) U.S. Cl. CPC G01R 31/2607

(57) ABSTRACT

A system and method for determining a thermal characteristic of an electronic device is presented. A controller is configured to cause a voltage source to forward-bias a transistor. A thermal slope of the control terminal of the transistor is determined. A first voltage V₁ of the control terminal of the transistor is measured and a voltage pulse is applied across the first current carrying terminal and the second current carrying terminal of the transistor. A second voltage V₂ of the control terminal of the transistor is measured and a magnitude of a current ID flowing into the first current carrying terminal of the transistor is measured. The thermal resistance characteristic of the electronic device is determined using the first voltage, the second voltage, and the magnitude of the current.

### FIELD OF THE INVENTION

This disclosure relates generally to the field of semiconductor devices and the manufacture thereof and, more particularly, to approaches for determining the thermal resistance characteristics of a device incorporating semiconductor-based components.

### BACKGROUND

Electronic devices incorporating semiconductor components such as transistors dissipate power in the form of heat energy. Although some devices have ambient operating temperature ranges from 0 to 70° C., some devices, such as power amplifiers and, particularly those used in wireless communication systems, may have much higher operating temperatures up to 200° C. or higher. Because heat can be detrimental to such devices, to achieve adequate heat dissipation, semiconductor dies are typically packaged such that heat generated during operation of the die is transferred along one or more thermal paths to an external heat radiator of some sort. For example, in some devices, thermal energy travels by conduction through the die attach material, die pad, and solder joints where it may be absorbed by a heat dissipation structure (e.g., copper (Cu) slugs) and fed into an externally mounted heat sink that is configured to radiate that heat energy into the device's environment.

The efficiency at which heat energy passes from the semiconductor die, through the various heat-conductive structures, and into the device's heat sink(s) is referred to as the device's thermal resistance. If a device has high thermal resistance, the device is inefficient at radiating heat along that pathway, which can affect the device's performance—the device may be required to run a lower operating frequency and/or power levels to prevent device damage. In contrast, a device with low thermal resistance efficiently transfers heat into the device's heat radiating structures and may operate at higher frequencies and power levels.

Defects in the thermal path between a device's semiconductor dies and the device's heat sink can increase the device's thermal resistance and negatively affect the ability of the device to dissipate heat. For example, a defect in the adherence of the die to a corresponding die pad, such as a void or delamination in the die attach material, may reduce the ability of the semiconductor die to conductively transfer heat into heat radiating structures. As a result, the temperature of the semiconductor die may rise to a level that is above the normal or recommended operating range. As the temperature of the die increases, the performance of the die may be degraded.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

In the drawings:

FIG. 1 is a schematic diagram of a simplified Doherty amplifier.

FIG. 2 is a top view of an example of an RF amplifier module configured as a Doherty amplifier.

FIG. 3 is a cross-sectional view of the module of FIG. 2 taken along line 3-3 of FIG. 2.

FIG. 4 is a block diagram depicting a system for determining thermal characteristics of an electronic device.

FIG. 5 is a flowchart depicting a method that may be implemented by the controller of FIG. 4 to determine the thermal slope of V_{GS} of a transistor of an electronic device.

FIG. 6 is a block diagram depicting a system for determining thermal characteristics of an electronic device including first and second transistors.

FIG. 7 is a flowchart depicting a method that may be implemented by the controller of FIG. 6 to determine the thermal slopes of transistors of an electronic device.

FIG. 8 is a chart depicting example thermal slope data that may be generated using the method of FIG. 7.

FIG. 9 is a block diagram depicting a system for determining a thermal resistance characteristic of an electronic device.

FIG. 10 is a flowchart depicting a method for determining a thermal resistance characteristic of an electronic device using the system of FIG. 9.

FIG. 11 is a chart that includes a number of traces depicting various values associated with a transistor being tested according to the method of FIG. 10.

### DETAILED DESCRIPTION OF THE ILLUSTRATED EMBODIMENTS

This disclosure relates generally to the field of semiconductor devices and the manufacture thereof and, more particularly, to approaches for determining the thermal resistance characteristics of a device incorporating semiconductor-based components.

Within an electronic device, components that incorporate semiconductor die in integrated circuits can generate significant amounts of thermal energy as they dissipate power. Because excess heat can damage such components, proper operation of electronic devices often require an efficient thermal conductive pathway from the device's semiconductor die into the device's heatsinks or other heat-radiating structures. The thermal efficiency of such a thermal conductive pathway is referred to as the pathway's thermal resistance.

Generally, the lower the thermal resistance for a particular device, the more efficiently that device radiates heat from its heat-generating components, resulting in more efficient operation that, in turn, can enable device operation at higher frequencies and higher power levels as compared to other similarly configured devices exhibiting high thermal resistance characteristics.

Radio frequency (RF) amplifiers, for example, can generate substantial amounts of heat, which must be dissipated. To facilitate heat dissipation, such devices typically include a number of semiconductor components that are directly mounted to a substrate (e.g., a PCB) that incorporates thermally conductive structures (e.g., metal slugs), which dissipate heat generated by the semiconductor devices into a device flange and, ultimately, into a heatsink mounted to the device package. Because this thermal path includes a number of different components, the thermal resistance of the path is affected not only by the components themselves (e.g., the semiconductor die, conductive slugs, flange, and heatsink) but also by the manner in which the various components are connected to one another. Typically, these connections are formed by direct soldering or thermally conductive adhesive to ensure low thermal resistance between the components and, therefore, efficient heat energy transfer from one component to the next. However, if, during a manufacturing process, the connection between components is damaged or malformed (e.g., due to a poor soldering connection or component delamination), there may be significant thermal resistance at that connection point, which can reduce the thermal efficiency of the device.

If these issues arise during manufacturing of a device, it can be difficult to detect such defects without destructive inspections. That is, to inspect the quality of a solder or thermal adhesive connection within a particular electronic device, it is generally required to disassemble the device so that the connection can be inspected visually. Usually this disassembly is destructive (e.g., requiring cutting of the device to gain visual access to the physical connection being inspected) and so cannot be performed on devices as they are being manufactured.

The present disclosure, therefore, provides non-destructive approaches to determining thermal resistance characteristics of a device that has been or is undergoing manufacture. A described herein, once determined, the thermal resistance characteristics of a device can be used to determine whether the various thermal connections within the device are sufficient to ensure adequate heat management in the device. Conversely the determined thermal resistance characteristic could also indicate that the device is incapable of adequately radiating heat (e.g., the device's thermal resistance is too high), which may indicate an issue during manufacturing, such as a potential poor solder connections or a delamination issue.

An example of an electronic device that can be analyzed in accordance with the present disclosure is a Doherty amplifier, which can be used as an RF signal amplifier used in wireless communication systems. Doherty amplifiers are multi-stage amplifiers. Although various examples of the present disclosure are presented with reference to an electronic device configured as a Doherty signal amplifier, it should be understood that the thermal characteristic determination system and method of the present disclosure may be utilized in conjunction with any electronic devices that contain heat-generating components, such as a semiconductor die containing signal amplifiers, to detect potential issues with the manufacturing of the device, as described herein.

A two-way Doherty power amplifier includes a signal splitter with an input and two outputs, where each splitter output is connected to an input of a carrier amplifier or a peaking amplifier. The carrier and peaking amplifier outputs are electrically connected to a combining node, which is configured to combine (in phase) the amplified output signals from the carrier and peaking amplifiers. More particularly, in a “0-90” Doherty power amplifier, the output of one of the amplifiers is directly connected to the combining node, where the direct connection is desirably characterized by about 0 degrees of phase shift. Conversely, the output of the other amplifier is coupled to the combining node through an impedance inverter, which is characterized by about 90 degrees of phase shift. Typically, the impedance inverter consists of a series of conductive structures, including an impedance inverter line (e.g., a transmission line on a printed circuit board (PCB)).

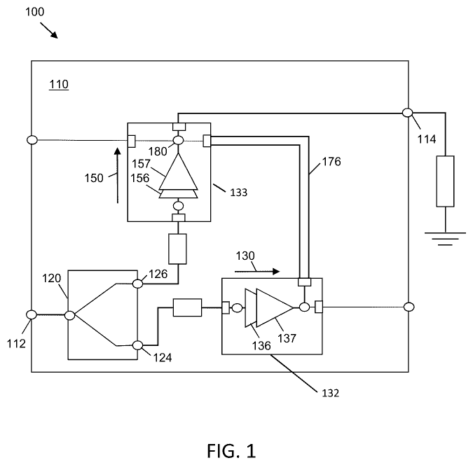

FIG. 1 is a schematic diagram of a simplified Doherty amplifier 100. Doherty amplifier 100 is formed over substrate 110. Doherty amplifier 100 includes an RF input node 112, an RF output node 114, a power or signal splitter 120, a carrier amplifier path 130, a peaking amplifier path 150, an impedance inverter line 176, and a combining node 180, in an embodiment.

The outputs 124, 126 of the power splitter 120 are connected to the carrier and peaking amplifier paths 130, 150, respectively. The carrier amplifier path 130 is configured to amplify the carrier signal from the power splitter 120, and to provide the amplified carrier signal to the power combining node 180. Similarly, the peaking amplifier path 150 is configured to amplify the peaking signal from the power splitter 120, and to provide the amplified peaking signal to the power combining node 180, where the paths 130, 150 are designed so that the amplified carrier and peaking signals arrive substantially in phase with each other at the power combining node 180.

Each amplification stage 136, 137 of the carrier amplifier device 132 includes a power transistor. Similarly, each amplification stage 156, 157 of the peaking amplifier device 133 includes a power transistor.

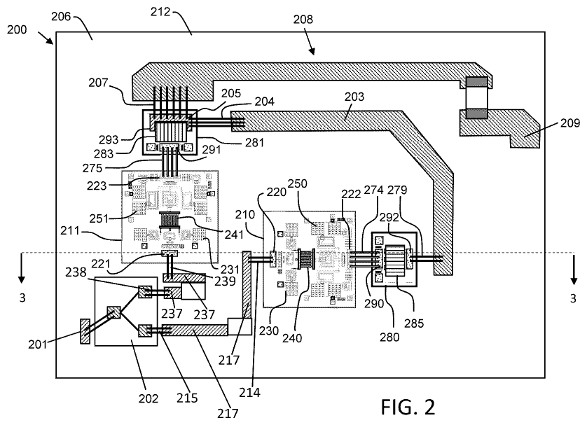

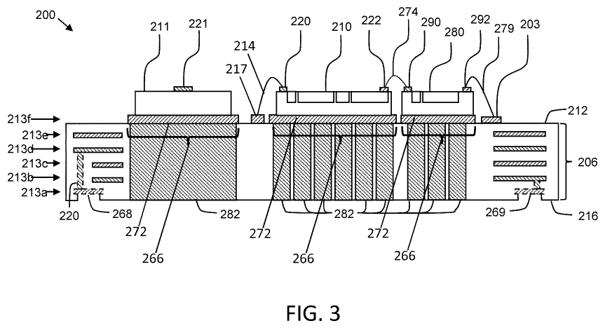

FIG. 2 is a top view of an example of an RF amplifier module 200 configured as a Doherty amplifier as in Doherty amplifier 100 of FIG. 1. FIG. 3 is a cross-sectional view of module 200 taken along line 3-3 of FIG. 2. RF amplifier module 200 includes a Doherty amplifier, in an embodiment, though in other embodiments, module 200 could include other types of amplifier and electrical circuits. Because, in the depicted embodiment, module 200 is self-contained and includes a Doherty amplifier, RF amplifier module 200 may alternatively be referred to below as a “Doherty power amplifier module.”

According to an embodiment, the Doherty amplifier module 200 is implemented as a module with terminals exposed at a bottom surface, such as, for example a land grid array (LGA) module. More specifically, the Doherty power amplifier module 200 includes a substrate 206, which may include a multiple layer printed circuit board (PCB) with a component mounting surface 212 and an opposed land surface 216.

The substrate 206 includes a plurality of dielectric material layers (e.g., formed from FR-4, ceramic, or other PCB dielectric materials), and a plurality of conductive (e.g., metal) layers 213a-213f, which are separated by the dielectric material of the dielectric material layers. In an embodiment, the conductive layer 213f on the component mounting surface 212 of the substrate 206 is a patterned conductive layer. Various conductive features (e.g., conductive die pads 272 and traces) formed from portions of the top patterned conductive layer may serve as attachment points for dies 210, 211, 280, 281 and other discrete components, and also may provide electrical connectivity between the dies 210, 211, 280, 281 and the other discrete components. Another conductive layer may serve as a ground reference plane. In some embodiments, the additional patterned conductive layers may provide conductive connections between the dies 210, 211, 280, 281, the discrete components, and the ground reference plane. According to an embodiment, a bottom conductive layer 213a is utilized to provide backside externally accessible conductive landing pads 268, 269 that may be used to electrically and mechanically couple module 200 and components thereof to external components, for example. In the depicted embodiment, landing pad 268 may be electrically connected (e.g., via one or more of metal layers 213a-213f and conductive vias) to input terminal 201 at the mounting surface 212. Similarly, landing pad 269 may be electrically connected to output terminal 209 at the mounting surface 212. These various landing pads (among others, not illustrated) enable surface mounting of the Doherty power amplifier module 200 onto a separate substrate that provides electrical connectivity to other portions of an RF system.

Doherty power amplifier module 200 further includes RF signal input terminal 201, RF signal output terminal 209, a power splitter 202, a carrier amplifier path that includes a cascade-coupled driver stage die 210 and final stage die 280, a peaking amplifier path that includes a cascade-coupled driver stage die 211 and final stage die 281, various phase shift and impedance matching elements, and a combiner.

Each of the components of amplifier module 200 and, specifically, carrier and peaking amplifier dies 210, 211, 280, 281 may produce significant amounts of heat during operation. In addition, each of the carrier and peaking amplifier dies 210, 211, 280, 281 may also need access to a ground reference. Accordingly, in an embodiment of module 200, substrate 206 also includes a plurality of electrically and thermally conductive trenches to which the carrier and peaking amplifier dies 210, 211, 280, 281 are coupled via a thermally conductive material (e.g., with solder, brazing material, sinter, or other die attach materials) so that the dies 210, 211, 280, 281 are thermally and electrically coupled to the thermally conductive trenches 282. The trenches 282 extend through the substrate 206 thickness in die mounting zones 266 of substrate 206 to provide heat sinks and ground reference access to the carrier and peaking amplifier dies 210, 211, 280, 281. For example, the conductive trenches 282 may be filled with copper or another thermally and electrically conductive material. In alternate embodiments, the trenches 282 may be replaced with other types of heat-conveying structures, such as conductive slugs (e.g., copper slugs) or thermal vias.

The power splitter 202, which is coupled to the mounting surface 212 of the substrate 206 and comprises an input circuit of module 200, may include one or more discrete die and/or components, although it is represented in FIG. 2 as a single element. The input circuit of module 200 may more generally be considered ‘circuitry’ or ‘amplifier circuitry’ that is coupled to the mounting surface 212 of the substrate 206. The power splitter 202 includes an input terminal and two output terminals. The input terminal of the power splitter 202 is electrically coupled through one or more conductive structures (e.g., vias, traces, and/or wirebonds) to the input terminal 201 to receive an input RF signal. The output terminals of the power splitter 202 are electrically coupled through one or more conductive structures (e.g., vias, traces 217, 237, and/or wirebonds 215, 214, 238, 239) to input terminals 220, 221 for the carrier and peaking amplifiers, respectively.

The first output of power splitter 202 is electrically coupled to the carrier amplifier path (i.e., to the carrier amplifier), and the second output of the power splitter is electrically coupled to the peaking amplifier path (i.e., to the peaking amplifier).

The first RF signal produced by the power splitter 202 is amplified through the carrier amplifier path, which includes the driver stage die 210, the final stage die 280, and impedance inverter element 203 that includes an impedance inverter and phase shifter. The second RF signal produced by the power splitter 202 is amplified through the peaking amplifier path, which includes the driver stage die 211, the final stage die 281.

The first output of the power splitter 202 is electrically coupled to an input terminal 220 of the driver stage die 210 (corresponding to a carrier amplifier input) through various conductive traces, circuitry, and wirebonds or other types of electrical connections. The driver stage die 210 and the final stage die 280 of the carrier amplifier path are electrically coupled together in a cascade arrangement between the input terminal 220 of the driver stage die 210 and an output terminal 292 of the final stage die 280 (corresponding to a carrier amplifier output). The driver stage die 210 includes the input terminal 220, an output terminal 222, an input impedance matching circuit 230, a power transistor 240, and an integrated portion of an interstage impedance matching circuit 250, in an embodiment.

The final stage die 280 includes an input terminal 290, an output terminal 292, and a power transistor 28. The output terminal 222 of the driver stage die 210 is electrically coupled to the input terminal 290 of the final stage die 280 through a wirebond array 274 or another type of electrical connection. The input terminal 290 is electrically coupled to the gate of the power transistor 285.

An amplified first RF signal is produced at the output terminal 292 of the final stage die 280. According to an embodiment, the output terminal 292 is electrically coupled (e.g., through wirebonds 279 or another type of electrical connection) to impedance inverter element 203. According to an embodiment, impedance inverter element 203 has a first end that is proximate to the output terminal 292 of the final stage die 280, and a second end that is proximate to the output terminal 293 of the final stage die 281. For example, the impedance inverter element 203 may be implemented with an approximately lambda/4 (λ/4) transmission line (e.g., a microstrip transmission line with a 90 degree electrical length) that extends between its first and second ends. The impedance inverter element 203, along with the wirebonds 279, 204, may impart about a 90 degree relative phase shift to the amplified first RF signal as the signal travels from the phase shift element's first end to a combining node 205 coupled to its second end.

As mentioned above, the second RF signal produced by the power splitter 202 is amplified through the peaking amplifier path, which includes the driver stage die 211 and the final stage die 281. Accordingly, the second output of the power splitter 202 is electrically coupled to an input terminal 221 of the driver stage die 211 through various conductive traces, circuitry, and wirebonds or another type of electrical connection.

The driver stage die 211 and the final stage die 281 of the peaking amplifier path are electrically coupled together in a cascade arrangement between an input terminal 221 of the driver stage die 211 (corresponding to a peaking amplifier input) and an output terminal 293 of the final stage die 281 (corresponding to a peaking amplifier output). The driver stage die 211 includes a plurality of integrated circuits. In an embodiment, the integrated circuitry of die 211 includes the input terminal 221, an output terminal 223, an input impedance matching circuit 231, a power transistor 241, and an integrated portion of an interstage impedance matching circuit 251, in an embodiment.

The final stage die 281 includes a plurality of integrated circuits. In an embodiment, the integrated circuitry of die 281 includes an input terminal 291, an output terminal 293, and a power transistor 283.

The output terminal 223 of the driver stage die 211 is electrically coupled to the input terminal 291 of the final stage die 281 through a wirebond array 275 or another type of electrical connection. The input terminal 291 is electrically coupled to the gate of the power transistor 283.

In any event, the amplified second RF signal is produced by the final stage die 281 at the RF output terminal 293. According to an embodiment, the RF output terminal 293 is electrically coupled (e.g., through wirebonds 204 or another type of electrical connection) to the second end of the impedance inverter element 203. Accordingly, the amplified first RF signal produced by the final stage die 280 is conveyed to the RF output terminal 293, and the output terminal 293 functions as a combining node 205 for the amplified first and second RF signals. When the various phase shifts imparted separately on the first and second RF signals are substantially equal, the amplified first and second RF signals combine substantially in phase at combining node 205.

The RF output terminal 293 (and thus combining node 205) is electrically coupled (e.g., through wirebonds 207 or another type of electrical connection) to an output network 208, which functions to present the proper load impedances to each of carrier and peaking amplifier dies 280, 281. The output network 208 is electrically coupled to conductive output terminal 209. The output terminal 209 can function as the RF output node for the Doherty power amplifier module 200 for outputting an amplifier output signal. The output network 208 of module 200 may more generally be considered ‘circuitry’ or ‘amplifier circuitry’ that is coupled to the mounting surface 212 of the substrate 206.

The completed amplifier module 200, once constructed, can then be incorporated into a larger electronic device or end product.

To ensure proper operation of module 200, module 200 should exhibit adequate heat dissipation characteristics so that heat energy generated within its heat generating components (in this example, driver stage die 211, final stage die 281, driver stage die 210, and final stage die 280) is efficiently transmitted into the thermally conductive trenches 282 from which the heat can be radiate through a connected heat sink or other heat dissipating structure.

If, during fabrication of module 200, however, components of module 200 become delaminated or the soldered connections fail, module 200 may be incapable of radiating heat efficiently. For example, if the connection between one or more of conductive die pads 272 and driver stage die 211, final stage die 281, driver stage die 210, and final stage die 280 fails (e.g., due to lamination failure), the dies may be incapable of efficiently conducting heat into conductive die pads 272. Similarly, if the connection between conductive die pads 272 and trenches 282 fails, conductive die pads 272 may be incapable of efficiently conducting heat into trenches 282.

The present disclosure provides an approach for determining the thermal characteristics of a device, such as module 200, to enable detection of poor thermal connections between device components, such as those due to lamination failures or port solder connections.

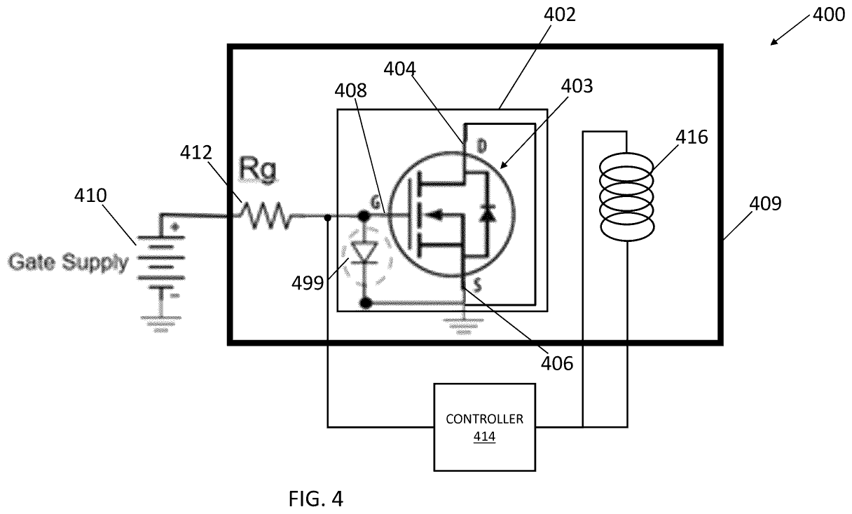

FIG. 4 is a block diagram depicting a system 400 for determining thermal characteristics of electronic device 402 (e.g., module 200 of FIGS. 2 and 3). In this example, electronic device 402 includes a transistor 403 having a first current carrying terminal or drain terminal (D) 404, a second current carry terminal or source terminal(S) 406, and a control terminal or gate terminal (G) 408. The voltage of gate terminal 408 controls the conductivity of the channel between drain terminal 404 and source terminal 406 within transistor 403. In various embodiments, transistor 403 of device 402 may be equivalent to one of the transistors (e.g., power transistor 241, or power transistor 240) of module 200. In that case, the first current carrying terminal of transistor 403 may be equivalent to the source terminals of power transistor 241 or power transistor 240). The control terminal 408 of transistor 403 may be equivalent to input terminal 221 of power transistor 241 or input terminal 220. The second current carrying terminal 404 of transistor 403 may be equivalent to output terminal 223 of power transistor 241 or output terminal 222 of power transistor 240.

In other embodiments, transistor 403 may be equivalent to the transistor or amplifier of final stage die 281 of module 200. In that case, the first current carrying terminal of transistor 403 may be equivalent to the source terminal of power transistor 283. The control terminal 408 of transistor 403 may be equivalent to input terminal 291 of power transistor 283. The second current carrying terminal 404 of transistor 403 may be equivalent to combining node 205 of power transistor 283.

In other embodiments, transistor 403 may be equivalent to the transistor or amplifier of final stage die final stage die 280 of module 200. In that case, the first current carrying terminal of transistor 403 may be equivalent to the source terminal of power transistor 285. The control terminal 408 of transistor 403 may be equivalent to 290 of power transistor 285. The second current carrying terminal 404 of transistor 403 may be equivalent to output terminal 292 of power transistor 285.

In various embodiments, system 400 may be utilized to iteratively test the thermal conductivity attributes and thermal resistance at each of the transistor devices of module 200, for example. In the specific example of module 400, four separate thermal capabilities tests may be performed in accordance with the present disclosure. However, it should be understood that system 400 may be utilized to evaluate the performance of electronic devices having different numbers of transistors, in which case the various transistors may each be evaluated in different test implementations using system 400.

The gate terminal 408 of transistor 403 is configured as a Schottky diode (illustrated by diode 499 connected between gate terminal 408 and source terminal 406) and, as such, if the transistor 403 is forward biased, such as by applying an appropriate biasing voltage to the gate terminal 408, and the drain terminal 404 and the source terminal 406 are at the same voltage, the voltage across the gate terminal 408 and source terminal 406 is dependent upon temperature.

Using this characteristic of transistor 403, system 400, as described below, is configured to determine the thermal slope behavior of the voltage of the forward biased gate terminal 408 (V_{GS}) for device 402. Specifically, the thermal slope of V_{GS} refers to the rate at which the voltage V_{GS} changes over temperature (e.g., measured in millivolts per degree Celsius (mV/C)).

To determine the thermal slope of V_{GS} for electronic device 402, system 400 includes a DC bias voltage source 410 connected to gate terminal 406 through resistor 412. The voltage of DC bias voltage source 410 is selected to forward-bias the transistor of electronic device 402. In some embodiments, the voltage of DC bias voltage source 410 may be in the range of 4 V to 6 V or greater (e.g., 5 V or greater) though other forward bias voltages may be utilized depending upon the configuration of transistor 403.

System 400 includes controller 414. Controller 414 may comprise, in various embodiment one or more processors and/or controller(s) of a general-purpose computer, special purpose computer, or other programmable data processing apparatus (e.g., controller) configured to execute computer-readable instructions or software code, such that the instructions, which execute via the processor(s) of the computer or other programmable data processing apparatus of controller 414, create circuitry or means for implementing the functions/acts described in accordance with system 400.

Controller 414 is connected to gate terminal 408 and is configured to measure a voltage of gate terminal 408. Controller 414 is also connected to heating element 416 and is configured to turn heating element 416 on or off to change the ambient temperature in proximity to electronic device 402 and, thereby, the temperature of electronic device 402 itself. As such, by controlling the operation of heating element 416, controller 414 can determine the temperature of electronic device 402. To provide precise temperature control, both heating element 416 and electronic device 402 may be disposed within a closed and insulated housing 409 enabling heating element 416 to precisely control the ambient temperature around device 402 and the temperature of device 402 itself as part of the determination of the thermal slope value for device 402. In such an implementation, for example, controller 414 may be implemented as a proportional-integral-derivative (PID) temperature controller configured to precisely control the temperature inside the closed housing 409. In that case, controller 414 may be coupled to one or more temperature sensors (not shown in FIG. 4) within the housing, which provide temperature feedback data enabling controller 414 to accurately determine the temperature within the housing 409.

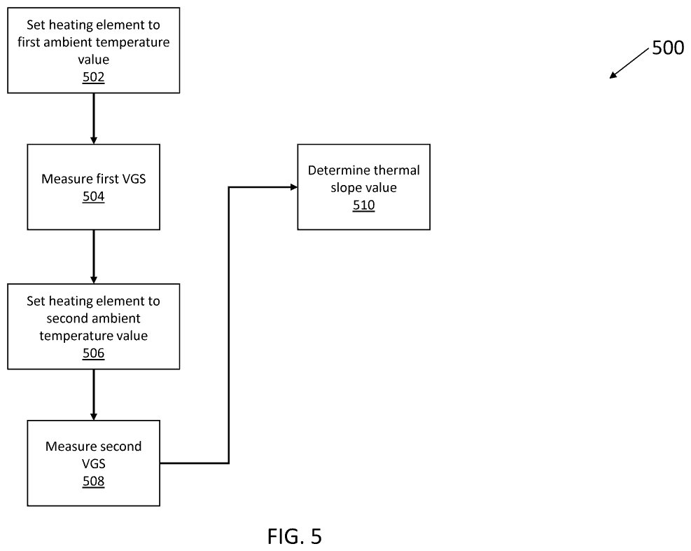

To determine the thermal slope of V_{GS} of the transistor of device 402, controller 414 is configured to measure V_{GS} at a number of different electronic device 402 temperatures. FIG. 5 is a flowchart depicting a method 500 that may be implemented by controller 414 of FIG. 4 to determine the thermal slope of V_{GS} of the transistor of device 402.

At block 502, controller 414 is configured to operate heating element 416 to cause electronic device 402 to have a first temperature. Controller 414 is then configured to wait until sufficient time has passed for heating element 416 to reach its desired temperature and for electronic device 402 to reach the first temperature. This time period may be determined by experiment (e.g., by testing system 400 to determine how long it takes a typical electronic device 402 to reach ambient temperature) and may be affected by factors such as the mass and materials making up electronic device 402.

Once electronic device 402 has reached the first temperature, at block 504 controller 414 is configured to measure a first voltage V_{GS1} between gate terminal 408 of transistor 403 and source terminal 406 of transistor 403 of electronic device 402.

After measuring the first voltage, at block 506 controller 414 is configured to operate heating element 416 to cause electronic device 402 to have a second temperature. Controller 414 is then configured to wait until sufficient time has passed for heating element 416 to reach its desired temperature and for electronic device 402 to reach the second temperature. Once electronic device 402 has reached the second temperature, at block 508 controller 414 is configured to measure a second voltage V_{GS2} between gate terminal 408 of transistor 403 and source terminal 406 of transistor 403 of electronic device 402.

Accordingly, at the completion of block 508, controller 414 has determined the values set forth in Table 1, below.

TABLE 1

| Temperature | V_{GS} |
|---|---|
| <first temperature> | <first voltage> |
| <second temperature> | <second voltage> |

Using those measurements, at block 510, controller 414 is configured to determine the thermal slope of the voltage V_{GS} using the following expression:

$$\frac{< s econd voltage > - < first voltage >}{< second temperature - < first temperature >} \qquad ( 1 )$$

In many transistor configurations, it is observed that the thermal slope characteristics of V_{GS} of a forward biased transistor having a Schottky-diode configured gate or control terminal is approximately linear and, as such, it may be adequate to determine the thermal slope value in accordance with method 500 using only two voltage measurements, presuming the two temperature values are sufficiently different. For example, a sufficiently accurate measurement of the thermal slope value may be achieved if the first temperature is around ambient room temperature (e.g., about 25 degrees Celsius) and the second temperature is about 50 degrees Celsius greater. In general, the first and second temperatures are selected based upon the configuration of transistor 403 being evaluated. In one approach multiple temperatures and corresponding V_{GS} values are measured in a testing setup. Based on that test data, the values of the first and second temperatures are selected as temperature values that result in a sufficient change in the measured voltage V_{GS} to provide adequately accurate thermal slope determinations that overcome errors in the measurement apparatus or other noise. For typical transistors the difference between the first temperature and the second temperature may be at least 20 degrees Celsius. In some embodiments the difference may be equal to 50 degrees Celsius.

If a more accurate thermal slope estimate is required, it would be possible to take three or more V_{GS} voltage measurements at different temperatures and estimate the slope value using those additional voltage measurements.

In an electronic device that includes multiple transistor-based amplifiers, it is possible to implement system 400 so that the thermal slope of the voltage V_{GS} of the multiple transistors can be determined at the same time with the test system. This may be useful, for example, when determining the thermal characteristics of components of a Doherty amplifier in which each of the carrier and peaking amplifiers are made up of two amplifier stages-a first driver stage amplifier and a second power amplifier connected in series.

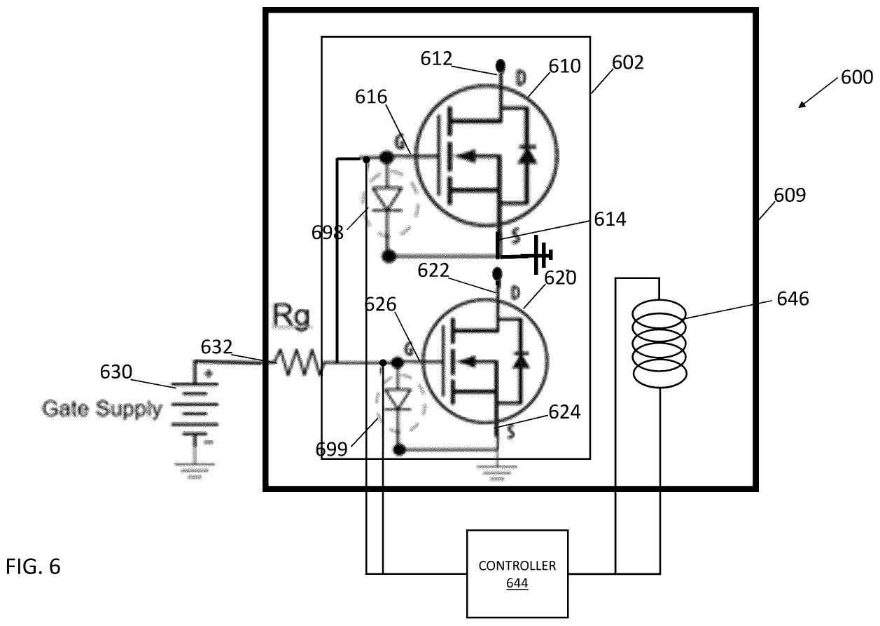

To illustrate, FIG. 6 is a block diagram depicting a system 600 for determining thermal characteristics of electronic device 602. In this example, electronic device 602 includes two amplifiers in parallel, where each amplifier includes a transistor 610, 620. As such, electronic device 602 could be equivalent to a Doherty amplifier that includes two amplifiers-a carrier amplifier and a peaking amplifier. In that case, transistor 610 may be equivalent to the carrier amplifier and transistor 620 could be equivalent to the peaking amplifier.

Each of transistors 610, 620 have Schottky-diode gate or controller terminals (illustrated by diode 698 connected between gate terminal 616 and source terminal 614 and by diode 699 connected between gate terminal 626 and source terminal 624) and include first current carrying terminals or drain terminals (D) 612, 622 (e.g., output terminal 292, if transistor 610 of electronic device 602 is equivalent to the main amplifier of module 200 and output terminal/combining node 205 if transistor 620 of electronic device 602 is equivalent to the power amplifier of module 200), second current carrying terminals or source terminal (S) 614, 624 which are connected to a ground terminal, and control terminals or gate terminals (G) 616, 626 (e.g., input terminal 290 if transistor 610 of electronic device 602 is equivalent to the main amplifier of module 200 and input terminal 291 if transistor 620 of electronic device 602 is equivalent to the peaking amplifier of module 200).

Transistors 610 and 620 are connected in parallel with source terminal 614 of transistor 610 being connected to ground and the source terminal 624 of transistor 620 are each connected to ground. Drain terminal 612 and 622 can be left floating, and the control or gate terminals 616, 626 are connected to their respective source terminals 614, 624.

System 600 includes a DC bias voltage source 630 connected to gate terminals 616, 626 through resistor 632. The voltage of DC bias voltage source 630 is selected to forward-bias both transistor 610 and 620 of electronic device 602.

System 600 includes controller 644. Controller 644 may comprise, in various embodiment one or more processors and/or controller(s) of a general-purpose computer, special purpose computer, or other programmable data processing apparatus (e.g., controller) configured to execute computer-readable instructions or software code, such that the instructions, which execute via the processor(s) of the computer or other programmable data processing apparatus of controller 644, create circuitry or means for implementing the functions/acts described in accordance with system 600.

Controller 644 is connected to gate terminals 616, 626 and is configured to measure the voltages of each gate terminal 616, 626. Controller 644 is also connected to heating element 646. By controlling the operation of heating element 646, controller 644 can determine an ambient temperature of electronic device 602. To provide precise temperature control, both heating element 646 and electronic device 602 may be disposed within a closed and insulated housing 609, enabling heating element 646 to precisely control the ambient temperature around device 602 as part of the determining of the V_{GS} thermal slope for device 602. In such an implementation, for example, controller 644 may be implemented as a PID temperature controller configured to precisely control the temperature inside the closed housing using heating element 646. In that case, controller 644 may be coupled to one or more temperature sensors within the housing, which provide temperature feedback data enabling controller 644 to accurately set the temperature within the housing.

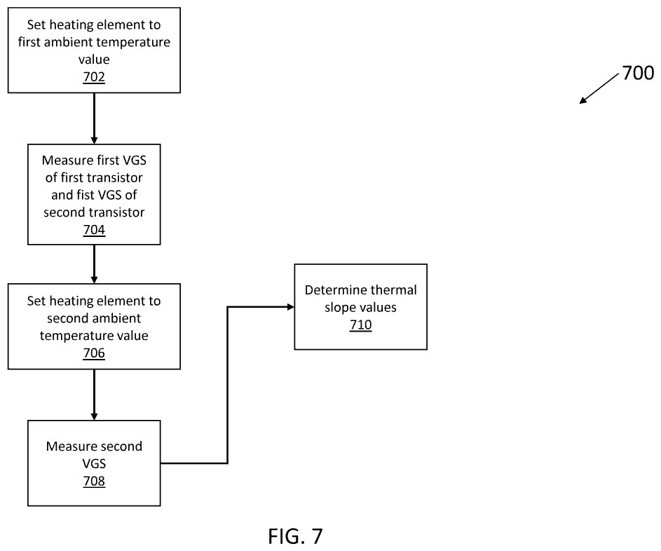

To determine the thermal slope of V_{GS} of the transistors 610, 620 of device 602, controller 644 is configured to measure V_{GS} of the transistors 610, 620 at a number of different ambient temperatures. FIG. 7 is a flowchart depicting a method 700 that may be implemented by controller 644 of FIG. 6 to determine the thermal slopes of the transistors 610, 620 of device 602.

At block 702, controller 644 is configured to operate heating element 646 to cause electronic device 602 to have a first temperature. Controller 644 is then configured to wait until sufficient time has passed for heating element 646 to reach its desired temperature and for electronic device 602 to reach the first temperature. This time period may be determined by experiment (e.g., by testing system 600 to determine how long it takes a typical electronic device 602 to reach ambient temperature).

Once electronic device 602 has reached the first temperature, at block 704 controller 644 is configured to measure a first voltage V_{GS1} of the first transistor 610 of electronic device 602 (i.e., the voltage different between control terminal 616 and source terminal 614 of first transistor 610) and a first voltage V_{GS1} of the second transistor 620 (i.e., the voltage difference between control terminal 626 and source terminal 624 of drain terminal 612) of electronic device 602.

After measuring the voltages, at block 706 controller 644 is configured to operate heating element 646 to cause electronic device 602 to have a second temperature. Controller 644 is then configured to wait until sufficient time has passed for heating element 646 to reach its desired temperature and for electronic device 602 to reach the second temperature. Once electronic device 602 has reached the second temperature, at block 708 controller 644 is configured to measure a second voltage V_{GS2} of the first transistor 610 of electronic device 602 and a second voltage V_{GS2} of the second transistor 620 of electronic device 602.

Accordingly, at the completion of block 708, controller 644 has determined the values set forth in Table 2, below.

TABLE 2

| | V_{GS} (first transistor | V_{GS} (second transistor |
|---|---|---|
| Ambient Temperature | 610) | 620) |
| <first temperature> | <first voltage> | <first voltage> |
| <second temperature> | <second voltage> | <second voltage> |

Using those measurements, at block 710, controller 644 is configured to determine the thermal slope of the voltage V_{GS} for the first transistor 610 using the following expression:

$$\frac{\begin{matrix}〈 second voltage , first transistor 〉 - \\ 〈 first voltage , first transistor 〉\end{matrix}}{〈 second temperature 〉 - 〈 first temperature 〉} \qquad ( 2 )$$

Controller 644 is configured to determine the thermal slop of the voltage V_{GS} for the second transistor 620 using the following expression:

$$\frac{\begin{matrix}〈 second voltage , second transistor 〉 - \\ 〈 first voltage , second transistor 〉\end{matrix}}{〈 second temperature 〉 - 〈 first temperature 〉} \qquad ( 3 )$$

In many transistor configurations, it is observed that the thermal slope characteristics of V_{GS} of a forward biased transistor having a Schottky-diode configured gate or control terminal is approximately linear and as such it may be adequate to determine the thermal slope value for both transistors 610, 620 in accordance with method 700 using only two voltage measurements for each transistor, presuming the two temperature values are sufficiently different.

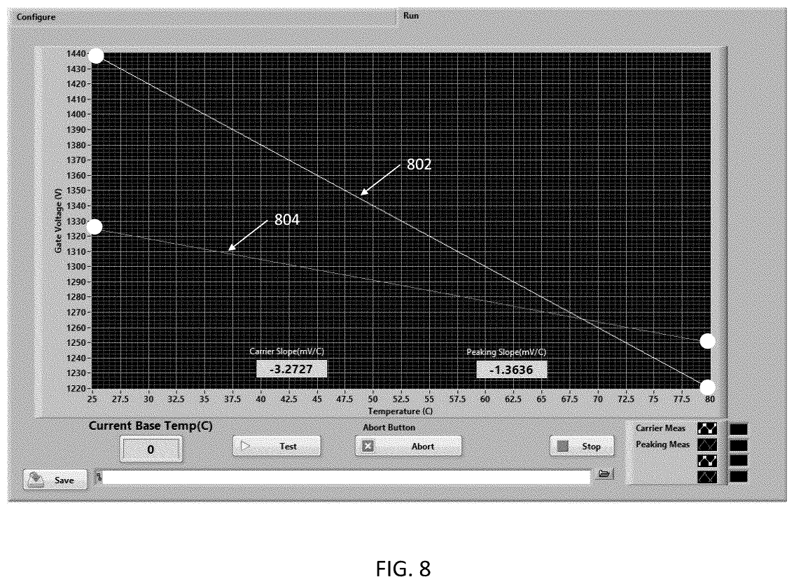

Following completion of method 700, thermal slopes have been determined for each transistor 610, 620 in device 602. FIG. 8 is a chart depicting example thermal slopes that may be generated using the method of FIG. 7. In FIG. 8, the horizontal axis represents temperature in degrees Celsius, while the vertical axis represents the voltage V_{GS}. Within FIG. 8 trace 802 represents the thermal slope of the voltage V_{GS} for the first transistor 610 of electronic device 602 and trace 804 represents the thermal slope of the voltage V_{GS} for the second transistor 620 of electronic device 602. As depicted, each thermal slope line is generated using two measurements. Trace 802, for example, is defined by a first voltage measurement captured at 25 degrees Celsius (e.g., the voltage measured for the first transistor 610 at block 704) and a second voltage measurement captured at 80 degrees Celsius (e.g., the voltage measured for the first transistor 610 at block 708). Similarly, trace 804, for example, is defined by a first voltage measurement captured at 25 degrees Celsius (e.g., the voltage measured for the second transistor 620 at block 704) and a second voltage measurement captured at 80 degrees Celsius (e.g., the voltage measured for the second transistor 620 at block 708).

With thermal slope values determined for the electronic device under test (e.g., for a device having a single transistor/amplifier using the method of FIG. 5 or for a device having two (or more) transistors/amplifiers using the method of FIG. 7), it is possible to characterize the electronic power dissipation characteristics to determine the rate at which the electronic device's internal temperature increases when under load, and, based on those power dissipation characteristics, the device's thermal resistance Rₜₕ.

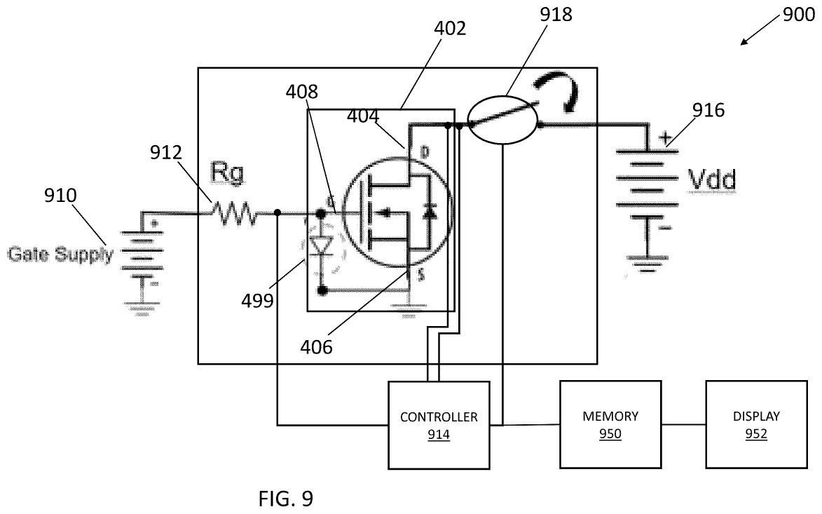

FIG. 9 is a block diagram depicting a system 900 for determining a thermal resistance characteristic of electronic device 402 of FIG. 4.

System 900, as described below, is configured to determine a thermal resistance characteristic of device 402. Specifically, system 900 is configured to subject the transistor of electronic device 402 to a relatively large drain voltage pulse, which results in significant DC voltage dissipation throughout electronic device 402 and, consequently, an increase in temperature of electronic device 402, which affects (pursuant to the thermal slope value determined above with respect to the method of FIG. 5) the V_{GS} of the transistor of electronic device 402. The change in V_{GS} can, in turn, as described below, be correlated to a thermal resistance Rₜₕ of electronic device 402.

As described herein, the thermal resistance Rₜₕ value can then be used as an indicator of a properly-constructed electronic device 402 or (e.g., if thermal resistance Rₜₕ falls below some threshold value) or an indicator that a defect that occurred during device fabrication, such as a structure delamination or solder joint failure, has rendered the device sufficiently thermally ineffective resulting in a need to repair the device (e.g., by performing solder reflow, or removing and remounting some comments) or, alternatively, discard the device.

System 900 includes a DC bias voltage source 910 connected to gate terminal 406 of the transistor of device 402 through resistor 912. The voltage of DC bias voltage source 910 is selected to forward-bias the transistor of electronic device 402. Drain terminal 404 is connected to a voltage source 916 through switch 918. Switch 918 is configured to selectively connect drain terminal 404 to that voltage source. Source terminal 406 is connected to a ground terminal.

Because, in this configuration with DC bias voltage source 910 connected to gate terminal 408 to forward bias the transistor of electronic device 402, when switch 918 is closed and drain terminal 404 is connected to voltage source 916, the transistor of electronic device 402 behaves as a short to ground, resulting in significant current passing through the conductive channel between drain terminal 404 and source terminal 406.

System 900 includes controller 914. Controller 914 may comprise, in various embodiment one or more processors and/or controller(s) of a general-purpose computer, special purpose computer, or other programmable data processing apparatus (e.g., controller) configured to execute computer-readable instructions or software code, such that the instructions, which execute via the processor(s) of the computer or other programmable data processing apparatus of controller 914, create circuitry or means for implementing the functions/acts described in accordance with system 900.

Controller 914 is connected to switch 918. Controller 914 is configured to operate switch 918 at a relatively high frequency so as to expose transistor to a relatively short voltage pulse, which results in a corresponding current pulse flowing through the transistor. In various embodiments, the duration of the pulse may be between 200 millisecond and 800 milliseconds although in other embodiments, pulses of different duration may be utilized.

In various embodiments, controller 914 may be configured to open and close switch 918 at a sufficiently high frequency that switch 918 may only be closed for a number of milliseconds (ms) (e.g., on the order of a few hundred—around 500—ms, such as between 200 ms and 800 ms) to send current pulses through the transistor of electronic device 402.

Controller 914 is connected to gate terminal 408 and is configured to measure a voltage V_{GS} at gate terminal 408 (i.e., where the voltage V_{GS} is the voltage different between gate terminal 408 and source terminal 406, which is connected to ground). Controller 914 is connected to drain terminal 404 and is configured to measure a current flow from voltage source 916 into drain terminal 404.

To determine the thermal resistance characteristic of device 402, controller 914 is configured to close switch 918 for a short period of time (e.g., around 500 ms) to send a current pulse through the transistor of device 402. Controller 914 measures the voltage V_{GS} immediately before and immediately after the current pulse is delivered.

Because the current pulse results in power dissipation through electronic device 402 and a resulting change in temperature of electronic device 402 it is possible to determine the thermal resistance of electronic device 402 using the two voltage measurements in combination with the earlier-determined thermal slope value.

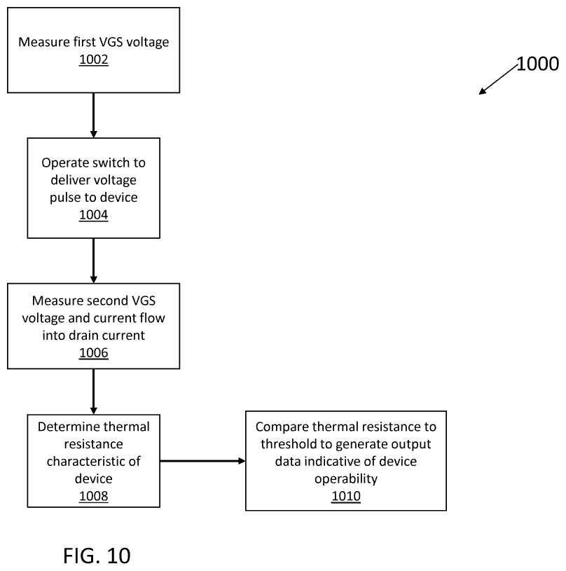

To illustrate, FIG. 10 is a flowchart depicting a method 1000 for determining a thermal resistance characteristic of electronic device 402 using system 900 of FIG. 9.

At block 1002, controller 914 is configured to measure a first voltage V_{GS1} of gate terminal 408 of electronic device 402.

At block 1004, controller 914 is configured to operate switch 918 to deliver a voltage pulse to the transistor of electronic device 402.

Immediately after delivering that current pulse (e.g., by closing and rapidly reopening switch 918), controller 914, at block 1006 is configured to measure a second voltage V_{GS2} of gate terminal 408 of electronic device 402. In one specific embodiment, controller 914 is configured to measure the second voltage V_{GS2} of gate terminal 408 at the same time (e.g., within 1 millisecond of) that the controller 914 ceases delivering the current pulse to the transistor of electronic device 402 (e.g., at the time controller 914 causes switch 918 to open). At that time, controller 914 also measures a current flow (I_{D}) into drain terminal 404 of the transistor of electronic device 402.

Because V_{GS} is dependent upon temperature, the amount by which V_{GS} has changed from the first voltage measurement to the second voltage measurement is indicative of an amount of change of temperature of device 402. The amount of temperature change is directly related to the thermal resistance of device 402. The greater the temperature change, the greater the thermal resistance of device 402 as device 402 has not effectively dissipated the thermal energy created by the power dissipated by that voltage pulse.

To be more specific, having captured the two voltage measurements of blocks 1002 and 1006, at block 1008 controller 914 is configured to determine the thermal resistance of device 402 using the following expressions. First controller 914 is configured to determine the temperature rise in device 402 resulting from the voltage pulse:

$${T}_{rise} = \frac{{V}_{GS 2} - {V}_{GS 1}}{〈 thermal\_slope 〉} \qquad ( 4 )$$

Where the value thermal_slope is determined according to method 500 of FIG. 5.

Having determined the Trise value, the thermal resistance of device 402 can be determined according to the following expression:

$${R}_{th} = \frac{{T}_{rise}}{{P}_{diss}} \qquad ( 5 )$$

Where the value P_{diss} is equal to the voltage of voltage source 916 multiplied by the current measurement I_{D}.

Expressions (4) and (5) may be combined to form the following expression:

$$\frac{\frac{{V}_{GS 2} - {V}_{GS 1}}{thermal slope}}{{V}_{GS 2} * {I}_{D}} \qquad ( 6 )$$

which is another way to determine the thermal resistance of device 402. Once the thermal resistance of device 402 is determined, at block 1010 the thermal resistance value can be analyzed (e.g., via comparison to one or more threshold values) to determine whether device 402 is exhibiting adequate thermal energy radiation characteristics to indicate proper fabrication and operation of the device. For example, in various uses of the present system, a number of known-good electronic devices 402 can be tested in this manner to characterize an acceptable thermal resistance value for the ultimate final product usage of electronic device 402. The value can then be used as a threshold such that if a newly manufacture electronic device 402 is tested and the thermal resistance value for that device falls below the acceptable thermal resistance value (indicating that the device exhibits adequate thermal radiation capacity) the device 402 can be incorporated into a final product. However, if the thermal resistance value for that device is above the acceptable thermal resistance value (indicating that the device does not exhibit adequate thermal radiation capacity) the device 402 may be considered to have failed quality inspection and may be sent to be repaired/rebuilt or may be discarded entirely. In an embodiment, an output of the comparison of the thermal resistance value to the predefined threshold may be stored in a memory 950 (e.g., a non-transitory computer readable medium) of controller 914. That value can then be accessed by a user interface or display 952 (e.g., a display screen, audible alert, or any other human-machine interface configured to output information to an operator of system 900) and the outcome of the comparison (e.g., that the device is properly manufactured or that the device being tested may be incapable of operating properly to due having a thermal resistance that exceeds the threshold) to alert an operator of system 900 that the device 402 is operating corrector or that device 402 may having problem that require follow-up investigation, remanufacture, or discarding of device 402.

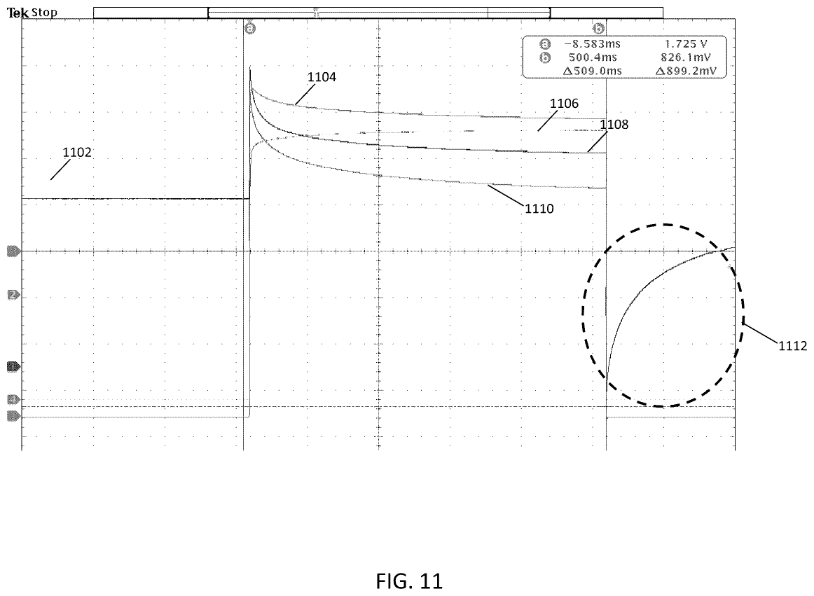

FIG. 11 is a chart that includes a number of traces depicting various values associated with a transistor being tested according to the method of FIG. 10. The horizontal axis of chart 1100 depicts time, while the vertical axis depicts signal magnitude.

Trace 1102 represents the control signal being transmitted to switch 918. When 402 has a high value, the switch is open, when trace 1102 has a low value switch 918 is closed (and the voltage pulse of block 1004 is being delivered). Trace 1104 represents power dissipation through electronic device 402 being evaluated. Trace 1106 represents the voltage drop across electronic device 402 and trace 1108 represents the V_{GS} of the transistor of electronic device 402. Trace 1110 represents the current flow I_{DS} through the transistor of electronic device 402.

As illustrated by the chart of FIG. 11, immediately after the voltage pulse has been delivered to electronic device 402, which results in a significant change in trace 1108, the electronic device 402 begins cooling rapidly (as illustrated by the fast cooling response portion of trace 1110 illustrated by dashed circle 1112 on FIG. 11). As such, in an embodiment, the various voltage and current measurements (e.g., V_{GS2} and I_{DS}) are captured at the same time that switch 918 is opened and, therefore, immediately following (or at the termination of) application of the voltage pulse to electronic device 402. As described herein, immediately following may mean within 1 millisecond, although depending upon the implementation immediately following may include other time ranges.

In some aspects, the techniques described herein relate to a system, including: a first voltage source configured to connect to a control terminal of a transistor contained within an electronic device; and a controller configured to: operate the first voltage source to apply a forward-bias voltage to the control terminal of the transistor, measure a first voltage VGS1 of the control terminal of the transistor, apply a voltage pulse across a first current carrying terminal of the transistor and a second current carrying terminal of the transistor, measure a second voltage VGS2 of the control terminal of the transistor; measure a magnitude of a current ID flowing into the first current carrying terminal of the transistor, and determine a thermal resistance characteristic of the electronic device using the first voltage VGS1, the second voltage VGS2, and the magnitude of the current ID; and compare the thermal resistance characteristic to a threshold value; and based on the comparison of the thermal resistance characteristic to the threshold value, determine that the electronic device has a defect that will prevent the electronic device from operating effectively.

In some aspects, the techniques described herein relate to a system, wherein the controller is configured to: determine a thermal slope of the control terminal of the transistor, wherein the thermal slope defines a relationship between a voltage of the control terminal and a temperature of the electronic device; and determine the thermal resistance using the thermal slope of the control terminal.

In some aspects, the techniques described herein relate to a system, wherein the controller is configured to determine the thermal resistance using the expression.

In some aspects, the techniques described herein relate to a system, further including a heating element in thermal communication with the electronic device, wherein: the controller is coupled to the heating element; the controller is configured to determine a temperature of the electronic device; the controller is configured to determine the thermal slope by: measuring a third voltage VGS3 of the control terminal of the transistor; determining a first temperature T1 of the electronic device; operating the heating element to modify a temperature of the electronic device; measuring a fourth voltage VGS4 of the control terminal of the transistor; determining a second temperature T2 of the electronic device; and determining the thermal slope using the expression.

In some aspects, the techniques described herein relate to a system, wherein the electronic device and the heating element are disposed within a thermally insulative housing.

In some aspects, the techniques described herein relate to a system, wherein the first current carrying terminal of the transistor is electrically connected to the second current carrying terminal of the transistor when the controller measures the third voltage VGS3 and the fourth voltage VGS4.

In some aspects, the techniques described herein relate to a system, further including a switch connected to the first currently carrying terminal and a second voltage source connected to the switch, wherein when the switch is closed a voltage of the second voltage source is applied to the first current carrying terminal.

In some aspects, the techniques described herein relate to a system, wherein when applying the voltage pulse, the controller is configured to close the switch for a time period having a duration that is between 200 millisecond and 800 milliseconds.

In some aspects, the techniques described herein relate to a system, wherein the controller is configured to measure the second voltage within one millisecond of opening the switch.

In some aspects, the techniques described herein relate to a system, wherein a magnitude of a voltage of the voltage pulse is equal to or greater than five volts.

In some aspects, the techniques described herein relate to a system, including: a controller configured to couple to a transistor, wherein the transistor includes a control terminal, a first current carrying terminal, and a second current carry terminal and the transistor is forward biased, the control being configured to: cause a voltage source to forward-bias the transistor, determine a thermal slope of the control terminal of the transistor, measure a first voltage V1 of the control terminal of the transistor, apply a voltage pulse across the first current carrying terminal and the second current carrying terminal of the transistor, measure a second voltage V2 of the control terminal of the transistor; measure a magnitude of a current ID flowing into the first current carrying terminal of the transistor, and determine a thermal resistance characteristic of the electronic device using the first voltage, the second voltage, and the magnitude of the current.

In some aspects, the techniques described herein relate to a system, further including a heating element in thermal communication with the electronic device, wherein: the controller is coupled to the heating element and is configured to; determine a temperature of the electronic device; determine the thermal slope by: measuring a third voltage VGS3 of the control terminal of the transistor; determining a first temperature T1 of the electronic device; operating the heating element to modify a temperature of the electronic device; measuring a fourth voltage VGS4 of the control terminal of the transistor; determining a second temperature T2 of the electronic device; and determining the thermal slope using the expression.

In some aspects, the techniques described herein relate to a system, further including a switch connected to the first currently carrying terminal and a second voltage source connected to the switch, wherein when the switch is closed a voltage of the second voltage source is applied to the first current carrying terminal.

In some aspects, the techniques described herein relate to a system, wherein when applying the voltage pulse, the controller is configured to close the switch for a time period having a duration that is between 200 millisecond and 800 milliseconds.

In some aspects, the techniques described herein relate to a system wherein the controller is configured to measure the second voltage within one millisecond of opening the switch.

In some aspects, the techniques described herein relate to a method, including: forward-biasing a transistor, the transistor including a control terminal, a first current carrying terminal, and a second current carry terminal; measuring a first voltage V1 of the control terminal of the transistor, applying a voltage pulse across the first current carrying terminal and the second current carrying terminal of the transistor; measuring a second voltage V2 of the control terminal of the transistor; measuring a magnitude of a current ID flowing into the first current carrying terminal of the transistor, and determining a thermal resistance characteristic of the electronic device using the first voltage, the second voltage, and the magnitude of the current.

In some aspects, the techniques described herein relate to a method, further including: determining a thermal slope of the control terminal of the transistor, wherein the thermal slope defines a relationship between a voltage of the control terminal and a temperature of the electronic device; and determining the thermal resistance using the thermal slope of the control terminal.

In some aspects, the techniques described herein relate to a method, further including determining the thermal slope by: measuring a third voltage V3 of the control terminal of the transistor; determining a first temperature T1 of the electronic device; operating the heating element to modify a temperature of the electronic device; measuring a fourth voltage V4 of the control terminal of the transistor; determining a second temperature T2 of the electronic device; and determining the thermal slope using the expression.

In some aspects, the techniques described herein relate to a method, further including applying the voltage pulse across the first current carrying terminal and the second current carrying terminal of the transistor for a time period having a duration that is less than 800 milliseconds.

In some aspects, the techniques described herein relate to a method, further including measuring the second voltage within one millisecond of applying the voltage pulse across the first current carrying terminal and the second current carrying terminal of the transistor.

As will be appreciated by one skilled in the art, aspects of the present disclosure may be embodied as a system, process, method, and/or program product. Accordingly, various aspects of the present disclosure (e.g., the machine learning system) may take the form of an entirely hardware embodiment, an entirely software embodiment (including firmware, resident software, micro-code, etc.), or embodiments combining software and hardware aspects, which may generally be referred to herein as a “circuit,” “circuitry,” “module,” or “system.” Furthermore, aspects of the present disclosure may take the form of a program product embodied in one or more computer readable storage medium(s) having computer readable program code embodied thereon. (However, any combination of one or more computer readable medium(s) may be utilized. The computer readable medium may be a computer readable signal medium or a computer readable storage medium.)

A computer readable storage medium may be, for example, but not limited to, an electronic, magnetic, optical, electromagnetic, infrared, biologic, atomic, or semiconductor system, apparatus, controller, or device, or any suitable combination of the foregoing, wherein the computer readable storage medium is not a transitory signal per se. More specific examples (a non-exhaustive list) of the computer readable storage medium may include the following: an electrical connection having one or more wires, a portable computer diskette, a hard disk, a random access memory (“RAM”), a read-only memory (“ROM”), an erasable programmable read-only memory (“EPROM” or flash memory), an optical fiber, a portable compact disc read-only memory (“CD-ROM”), an optical storage device, a magnetic storage device, or any suitable combination of the foregoing. In the context of this document, a computer readable storage medium may be any tangible medium that can contain or store a program for use by or in connection with an instruction execution system, apparatus, controller, or device. Program code embodied on a computer readable signal medium may be transmitted using any appropriate medium, including but not limited to wireless, wire line, optical fiber cable, RF, etc., or any suitable combination of the foregoing.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, controller, or device.

The block diagrams in the figures illustrate architecture, functionality, and operation of possible implementations of circuitry, systems, methods, processes, and program products according to various embodiments of the present disclosure. In this regard, certain blocks in the block diagrams may represent a module, segment, or portion of code, which includes one or more executable program instructions for implementing the specified logical function(s). It should also be noted that, in some implementations, the functions noted in the blocks may occur out of the order noted in the figures. For example, two blocks shown in succession may, in fact, be executed substantially concurrently, or the blocks may sometimes be executed in the reverse order, depending upon the functionality involved.

Modules implemented in software for execution by various types of processors may, for instance, include one or more physical or logical blocks of computer instructions, which may, for instance, be organized as an object, procedure, or function. Nevertheless, the executables of an identified module need not be physically located together but may include disparate instructions stored in different locations which, when joined logically together, include the module, and achieve the stated purpose for the module. Indeed, a module of executable code may be a single instruction, or many instructions, and may even be distributed over several different code segments, among different programs, and across several memory devices. Similarly, operational data (e.g., knowledge bases of adapted weights and/or biases described herein) may be identified and illustrated herein within modules and may be embodied in any suitable form and organized within any suitable type of data structure. The operational data may be collected as a single data set or may be distributed over different locations including over different storage devices. The data may provide electronic signals on a system or network.

These program instructions may be provided to one or more processors and/or controller(s) of a general-purpose computer, special purpose computer, or other programmable data processing apparatus (e.g., controller) to produce a machine, such that the instructions, which execute via the processor(s) of the computer or other programmable data processing apparatus, create circuitry or means for implementing the functions/acts specified in the block diagram block or blocks.

It will also be noted that each block of the block diagrams, and combinations of blocks in the block diagrams, can be implemented by special purpose hardware-based systems (e.g., which may include one or more graphics processing units) that perform the specified functions or acts, or combinations of special purpose hardware and computer instructions. For example, a module may be implemented as a hardware circuit including custom VLSI circuits or gate arrays, off-the-shelf semiconductors such as logic chips, transistors, controllers, or other discrete components. A module may also be implemented in programmable hardware devices such as field programmable gate arrays, programmable array logic, programmable logic devices, application specific ICs, microcontrollers, systems on a chip, general purpose processors, microprocessors, or the like.

Computer program code, i.e., instructions, for carrying out operations for aspects of the present disclosure may be written in any combination of one or more programming languages, including an object-oriented programming language such as Java, Smalltalk, Python, C++, or the like, conventional procedural programming languages, such as the “C” programming language or similar programming languages, or any of the machine learning software disclosed herein.

These program instructions may also be stored in a computer readable storage medium that can direct a computer system, other programmable data processing apparatus, controller, or other devices to function in a particular manner, such that the instructions stored in the computer readable medium produce an article of manufacture including instructions which implement the functions/acts specified in the block diagram block or blocks.

The program instructions may also be loaded onto a computer, other programmable data processing apparatus, controller, or other devices to cause a series of operational steps to be performed on the computer, other programmable apparatus or other devices to produce a computer implemented process such that the instructions which execute on the computer, other programmable apparatus, or other devices provide processes for implementing the functions/acts specified in the block diagram block or blocks.

The preceding detailed description is merely illustrative in nature and is not intended to limit the embodiments of the subject matter or the application and uses of such embodiments.

As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, or detailed description.

The connecting lines shown in the various figures contained herein are intended to represent exemplary functional relationships and/or physical couplings between the various elements. It should be noted that many alternative or additional functional relationships or physical connections may be present in an embodiment of the subject matter. In addition, certain terminology may also be used herein for the purpose of reference only, and thus are not intended to be limiting, and the terms “first”, “second” and other such numerical terms referring to structures do not imply a sequence or order unless clearly indicated by the context.

As used herein, a “node” means any internal or external reference point, connection point, junction, signal line, conductive element, or the like, at which a given signal, logic level, voltage, data pattern, current, or quantity is present. Furthermore, two or more nodes may be realized by one physical element (and two or more signals can be multiplexed, modulated, or otherwise distinguished even though received or output at a common node).

The foregoing description refers to elements or nodes or features being “connected” or “coupled” together. As used herein, unless expressly stated otherwise, “connected” means that one element is directly joined to (or directly communicates with) another element, and not necessarily mechanically. Likewise, unless expressly stated otherwise, “coupled” means that one element is directly or indirectly joined to (or directly or indirectly communicates with, electrically or otherwise) another element, and not necessarily mechanically. Thus, although the schematic shown in the figures depict one exemplary arrangement of elements, additional intervening elements, devices, features, or components may be present in an embodiment of the depicted subject matter.

While at least one exemplary embodiment has been presented in the foregoing detailed description, it should be appreciated that a vast number of variations exist. It should also be appreciated that the exemplary embodiment or embodiments described herein are not intended to limit the scope, applicability, or configuration of the claimed subject matter in any way. Rather, the foregoing detailed description will provide those skilled in the art with a convenient road map for implementing the described embodiment or embodiments. It should be understood that various changes can be made in the function and arrangement of elements without departing from the scope defined by the claims, which includes known equivalents and foreseeable equivalents at the time of filing this patent application.

What is claimed:

1. A system, comprising:
a first voltage source configured to connect to a control terminal of a transistor contained within an electronic device; and
a controller configured to:
operate the first voltage source to apply a forward-bias voltage to the control terminal of the transistor,
measure a first voltage V_{GS1} of the control terminal of the transistor,
apply a voltage pulse across a first current carrying terminal of the transistor and a second current carrying terminal of the transistor,
measure a second voltage V_{GS2} of the control terminal of the transistor;
measure a magnitude of a current ID flowing into the first current carrying terminal of the transistor, and
determine a thermal resistance characteristic of the electronic device using the first voltage V_{GS1}, the second voltage V_{GS2}, and the magnitude of the current ID; and
compare the thermal resistance characteristic to a threshold value; and
based on the comparison of the thermal resistance characteristic to the threshold value, determine that the electronic device has a defect that will prevent the electronic device from operating effectively.

2. The system of claim 1, wherein the controller is configured to:
determine a thermal slope of the control terminal of the transistor, wherein the thermal slope defines a relationship between a voltage of the control terminal and a temperature of the electronic device; and
determine the thermal resistance using the thermal slope of the control terminal.

3. The system of claim 1, wherein the controller is configured to determine the thermal resistance using the expression
$$\frac{\frac{{V}_{GS 2} - {V}_{GS 1}}{thermal slope}}{{V}_{GS 2} * {I}_{D}} .$$

4. The system of claim 2, further comprising a heating element in thermal
communication with the electronic device, wherein:
the controller is coupled to the heating element;
the controller is configured to determine a temperature of the electronic device;
the controller is configured to determine the thermal slope by:
measuring a third voltage V_{GS3} of the control terminal of the transistor;
determining a first temperature T₁ of the electronic device;
operating the heating element to modify a temperature of the electronic device;
measuring a fourth voltage V_{GS4} of the control terminal of the transistor;
determining a second temperature T₂ of the electronic device; and
determining the thermal slope using the expression
$$\frac{{V}_{GS 4} - {V}_{GS 3}}{{T}_{2} - {T}_{1}} .$$

5. The system of claim 4, wherein the electronic device and the heating element are disposed within a thermally insulative housing.

6. The system of claim 4, wherein the first current carrying terminal of the transistor is electrically connected to the second current carrying terminal of the transistor when the controller measures the third voltage V_{GS3} and the fourth voltage V_{GS4}.

7. The system of claim 1, further comprising a switch connected to the first currently carrying terminal and a second voltage source connected to the switch, wherein when the switch is closed a voltage of the second voltage source is applied to the first current carrying terminal.

8. The system of claim 7, wherein when applying the voltage pulse, the controller is configured to close the switch for a time period having a duration that is between 200 millisecond and 800 milliseconds.

9. The system of claim 8, wherein the controller is configured to measure the second voltage within one millisecond of opening the switch.

10. The system of claim 4, wherein a magnitude of a voltage of the voltage pulse is equal to or greater than five volts.

11. A system, comprising:
a controller configured to couple to a transistor, wherein the transistor includes a control terminal, a first current carrying terminal, and a second current carry terminal and the transistor is forward biased, the control being configured to:
cause a voltage source to forward-bias the transistor,
determine a thermal slope of the control terminal of the transistor,
measure a first voltage V₁ of the control terminal of the transistor,
apply a voltage pulse across the first current carrying terminal and the second current carrying terminal of the transistor,
measure a second voltage V₂ of the control terminal of the transistor;
measure a magnitude of a current ID flowing into the first current carrying terminal of the transistor, and
determine a thermal resistance characteristic of the electronic device using the first voltage, the second voltage, and the magnitude of the current.

12. The system of claim 11, further comprising a heating element in thermal communication with the electronic device, wherein:
the controller is coupled to the heating element and is configured to;
determine a temperature of the electronic device;
determine the thermal slope by:
measuring a third voltage V_{GS3} of the control terminal of the transistor;
determining a first temperature T₁ of the electronic device;
operating the heating element to modify a temperature of the electronic device;
measuring a fourth voltage V_{GS4} of the control terminal of the transistor;
determining a second temperature T₂ of the electronic device; and
determining the thermal slope using the expression
$$\frac{{V}_{GS 4} - {V}_{GS 3}}{{T}_{2} - {T}_{1}} .$$

13. The system of claim 12, further comprising a switch connected to the first currently carrying terminal and a second voltage source connected to the switch, wherein when the switch is closed a voltage of the second voltage source is applied to the first current carrying terminal.

14. The system of claim 13, wherein when applying the voltage pulse, the controller is configured to close the switch for a time period having a duration that is between 200 millisecond and 800 milliseconds.

15. The system of claim 14 wherein the controller is configured to measure the second voltage within one millisecond of opening the switch.

16. A method, comprising:
forward-biasing a transistor, the transistor including a control terminal, a first current carrying terminal, and a second current carry terminal;
measuring a first voltage V₁ of the control terminal of the transistor,
applying a voltage pulse across the first current carrying terminal and the second current carrying terminal of the transistor;
measuring a second voltage V₂ of the control terminal of the transistor;
measuring a magnitude of a current ID flowing into the first current carrying terminal of the transistor, and
determining a thermal resistance characteristic of the electronic device using the first voltage, the second voltage, and the magnitude of the current.

17. The method of claim 16, further comprising:
determining a thermal slope of the control terminal of the transistor, wherein the thermal slope defines a relationship between a voltage of the control terminal and a temperature of the electronic device; and
determining the thermal resistance using the thermal slope of the control terminal.

18. The method of claim 17, further comprising determining the thermal slope by:
measuring a third voltage V₃ of the control terminal of the transistor;
determining a first temperature T₁ of the electronic device;
operating the heating element to modify a temperature of the electronic device;
measuring a fourth voltage V₄ of the control terminal of the transistor;
determining a second temperature T₂ of the electronic device; and
determining the thermal slope using the expression
$$\frac{{V}_{4} - {V}_{4}}{{T}_{2} - {T}_{1}} .$$

19. The method of claim 16, further comprising applying the voltage pulse across the first current carrying terminal and the second current carrying terminal of the transistor for a time period having a duration that is less than 800 milliseconds.

20. The method of claim 16, further comprising measuring the second voltage within one millisecond of applying the voltage pulse across the first current carrying terminal and the second current carrying terminal of the transistor.
